(19) United States
(12) Patent Application Publication
(10) Pub. No.: US 2010/0261347 A1
(43) Pub. Date: Oct. 14, 2010

(54) SEMICONDUCTOR DEVICE AND METHOD OF FORMING THE SAME8027

(75) Inventor: HIDEKAZU NOBUTOH, Tokyo (JP)

Correspondence Address: YOUNG & THOMPSON, 209 Madison Street, Suite 500, Alexandria, VA, 22314, US

(73) Assignee: ELPIDA MEMORY, INC., TOKYO (JP)

(21) Appl. No.: 12/758,868

(22) Filed: Apr. 13, 2010

(30) Foreign Application Priority Data
Apr. 13, 2009 (JP) 2009-097034

(51) Int. Cl. H01L 21/768

(52) U.S. Cl. 438/672; 257/E21.585

(57) ABSTRACT

A method of forming a semiconductor device includes the following processes. A first insulating film is formed over an etching stopper film. The etching stopper film has wet-etching resistance. A second insulating film is formed over the second etching stopper. The second insulating film is higher in wet-etching rate than the first insulating film. An opening is formed, which penetrates the etching stopper and the first and second insulating films. A bottom electrode is formed in the opening. The second insulating film is removed by carrying out a wet etching process to expose the bottom electrode.

### BACKGROUND OF THE INVENTION

1. Field of the Invention

The present invention relates to a semiconductor device and a method of forming the same.

Priority is claimed on Japanese Patent Application No. 2009-097034, filed Apr. 13, 2009, the content of which is incorporated herein by reference.

2. Description of the Related Art

Japanese Unexamined Patent Application, First Publications, Nos. 2008-16688 and 2006-191025 disclose that shrinkage of semiconductor devices will generally reduce the area of memory cells of a DRAM (Dynamic Random Access Memory) device. In order to secure sufficient capacitance of capacitors for the memory cells, the capacitors have a three-dimensional structure. A bottom electrode of the capacitor has a cylindrical shape, a pillar shape, a columnar shape. An outside surface of the bottom electrode is used to ensure a sufficiently large capacity.

MIM (Metal Insulator Metal)-type capacitors have been generally used as electrode materials for the capacitor.

The capacitor can be formed using the outer wall of the bottom electrode of the capacitor. A bottom electrode is formed, which penetrates an interlayer insulating film. The outer surface of the bottom electrode is exposed. A dielectric film or an insulator film is formed which covers the outer surface of the bottom electrode.

The interlayer insulating film is generally formed by an insulating film containing silicon dioxide (SiO₂) as a main ingredient. A wet etching process can be used by using an etchant that contains hydrofluoric acid (HF) to remove the interlayer insulating film and expose the bottom electrode.

A silicon nitride (Si₃N₄) film having etching resistance to the etchant is provided so that the silicon nitride (Si₃N₄) film contacts the bottom of the bottom electrode of the capacitor. The silicon nitride (Si₃N₄) film will prevent a transistor from receiving any damage during wet etching process, wherein the transistor is positioned below the capacitor.

It is difficult that the silicon nitride film prevents penetration of the etchant. The etchant penetrated into the lower layer of the capacitor provides damages to the lower layer. The yield of manufacturing the semiconductor device such as a DRAM is lowered.

### SUMMARY

In one embodiment, a method of forming a semiconductor device may include, but is not limited to, the following processes. A first insulating film is formed on an etching stopper film. The etching stopper film has resistance to a wet-etching. A second insulating film is formed on the first insulating film. The second insulating film is higher in removing rate of the wet-etching than the first insulating film. An opening is formed, which penetrates the etching stopper and the first and second insulating films. A bottom electrode is formed in the opening. The second insulating film is removed by carrying out the wet-etching to expose an outside wall of the bottom electrode, wherein at least a part of the first insulating film remains on the etching stopper film after the wet-etching.

In another embodiment, a method of forming a device may include, but is not limited to, the following processes. An opening is formed in a first insulating layer. A conductive layer is formed on a bottom and a side surface of the opening. The conductive layer extends upwardly. The first insulating layer is selectively removed by a wet-etching to expose an outside wall of the conductive layer except for a lower portion thereof, while a remaining portion of the first insulating layer covers the lower portion of the conductive layer.

In still another embodiment, a method of forming a semiconductor device may include, but is not limited to, the following processes. A contact plug may be formed in an interlayer insulating film. An etching stopper film may be formed on the interlayer insulating film and the contact plug. A first insulating film may be formed on the etching stopper film. The etching stopper film has resistance to a wet-etching. A second insulating film may be formed on the second etching stopper. The second insulating film is higher in removing rate of the wet-etching than the first insulating film. An opening is formed, which penetrates the etching stopper and the first and second insulating films. A bottom electrode is formed in the opening. The second insulating film is removed by carrying out the wet-etching to expose an outside wall of the bottom electrode. The second insulating film is removed while the first insulating film covers the etching stopper film and a lower portion of the bottom electrode. The second insulating film prevents that an etchant penetrates through a boundary between the etching stopper and the bottom electrode, while carrying out the wet-etching.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary cross sectional elevation view of illustrating a semiconductor device in a step involved in a method of forming the semiconductor device in accordance with a first preferred embodiment of the present invention;

FIG. 2 is a fragmentary cross sectional elevation view of illustrating a semiconductor device in a step subsequent to the step of FIG. 1, involved in the method of forming the semiconductor device in accordance with the first preferred embodiment of the present invention;

FIG. 3 is a fragmentary cross sectional elevation view of illustrating a semiconductor device in a step subsequent to the step of FIG. 2, involved in the method of forming the semiconductor device in accordance with the first preferred embodiment of the present invention;

FIG. 4 is a fragmentary cross sectional elevation view of illustrating a semiconductor device in a step subsequent to the step of FIG. 3, involved in the method of forming the semiconductor device in accordance with the first preferred embodiment of the present invention;

FIG. 5 is a fragmentary cross sectional elevation view of illustrating a semiconductor device in a step subsequent to the step of FIG. 4, involved in the method of forming the semiconductor device in accordance with the first preferred embodiment of the present invention;

FIG. 6 is a plan view illustrating misalignments between conductive pads, contact plugs and bottom electrodes included in the semiconductor device in accordance with the first preferred embodiment of the present invention;

FIG. 7 is a fragmentary cross sectional elevation view illustrating the misalignments between conductive pads, contact plugs, and bottom electrodes, taken along a VII-VII line of FIG. 6;

FIG. 8 is a fragmentary cross sectional elevation view of illustrating a semiconductor device having a thin first insulating film in a step involved in the method of forming the semiconductor device in accordance with a modified embodiment of the present invention;

FIG. 9 is a fragmentary cross sectional elevation view of illustrating a semiconductor device in a step involved in the method of forming the semiconductor device in accordance with a modified embodiment of the present invention;

FIG. 10 is a fragmentary cross sectional elevation view of illustrating a semiconductor device in a step involved in the method of forming the semiconductor device in accordance with a modified embodiment of the present invention;

FIG. 11 is a fragmentary cross sectional elevation view of illustrating a semiconductor device in a step involved in the method of forming the semiconductor device in accordance with a modified embodiment of the present invention;

FIG. 12 is a fragmentary cross sectional elevation view of illustrating a semiconductor device in a step involved in the method of forming the semiconductor device in accordance with a modified embodiment of the present invention; and

FIG. 13 is a fragmentary cross sectional elevation view of illustrating a semiconductor device in a step involved in the method of forming the semiconductor device in the related art.

### DETAILED DESCRIPTION OF THE PREFERRED EMBODIMENTS

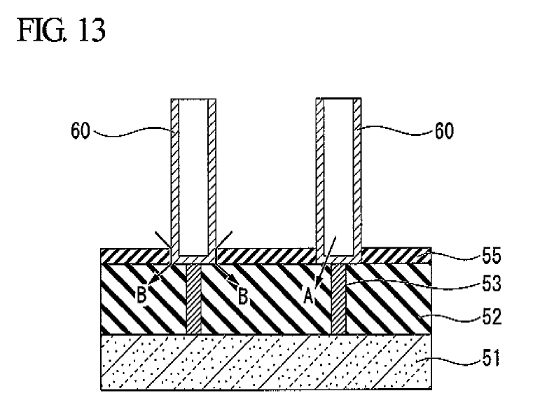

Before describing the present invention, the related art will be explained in detail with reference to FIG. 13, in order to facilitate the understanding of the present invention.

FIG. 13 is a fragmentary cross sectional elevation view illustrating a semiconductor device such as DRAM having capacitors of the related art.

An interlayer insulating film 52 containing silicon oxide is formed over a semiconductor substrate 51. Contact plugs 53 are provided over the semiconductor substrate 51. The contact plugs 53 are provided in the interlayer insulating film 52. A silicon nitride film 55 is provided over the surface of the interlayer insulating film 52. A bottom electrode 60 of a capacitor is formed in a cylindrical shape. The bottom electrode 60 penetrates the silicon nitride film 55 and contacts the contact plug 53. The bottom electrode 60 except for the lower portion thereof is exposed. FIG. 13 shows that the interlayer insulating film of silicon oxide has been removed by a wet etching process. The interlayer insulating film was formed over the silicon nitride film 55. The wet etching process may be carried out using hydrofluoric acid as an etchant.

The wet etching process using hydrofluoric acid to etch the interlayer insulating film of silicon oxide shows the following phenomenon. As the lower portion of the bottom electrode 60 and the silicon nitride film are exposed to the etchant for long time, hydrofluoric acid can soak into the interlayer insulating film 52 through paths indicated by arrow marks A and B in FIG. 13.

The etchant can be penetrated through the path A into an electrode material located at the bottom of the bottom electrode 60, and soak into the interlayer insulating film 52 of the lower layer. This phenomenon occurs when a metal such as titanium nitride (TiN) is used for the bottom electrode 60, because titanium nitride has the columnar crystal structure. An etchant is penetrated along crystalline grain interfaces. When the film thickness of the bottom electrode 60 is thin, the etchant can be penetrated into the lower layer.

The etchant can be penetrated through the path B into the lower layer. The path B is between the silicon nitride film 55 and the bottom electrode 60.

Japanese Unexamined Patent Application, First Publication, No. 2006-191025 discloses that an amorphous carbon film is provided on the silicon nitride film 55 in order to prevent that the etchant relating is penetrated through the path B.

Silicon oxide and amorphous carbon used in the interlayer insulating film are different in composition from each other. Conditions for carrying out the dry etching processes to form holes in the silicon oxide film and the amorphous carbon film are different. With shrinkage of the semiconductor device, it is necessary to form an opening of a high aspect ratio for forming the electrode. Increasing the aspect ratio of the opening makes it difficult to ensure the predetermined shape of the opening when formed by the dry etching process. It is difficult to maintain the desired shape of the opening, particularly the bottom shape thereof. When a foreign material such as amorphous carbon is provided at the bottom of the opening, it is further difficult to ensure the desired shape of the opening. If the shape of the opening is different from the desired shape, electrical connection can not be ensured. It is necessary to carry out an additional process for removing the amorphous carbon after the bottom electrode is formed.

It is possible to suppress penetration of the etchant through the path B by increasing the film thickness of the silicon nitride film 55, without providing the amorphous carbon film. Similarly to the amorphous carbon, the silicon nitride film at the bottom of the capacitor electrode is not preferable for forming the opening. It is preferable to reduce the film thickness as many as possible.

It is preferable to reduce the thickness of the silicon nitride film 55 as many as possible, for example, not more than about 50 nm, in order to relax the stress that can be applied to the semiconductor substrate.

It is difficult to prevent penetration of etchant by a single layered structure of the silicon nitride film 55.

The invention will be now described herein with reference to illustrative embodiments. Those skilled in the art will recognize that many alternative embodiments can be accomplished using the teaching of the present invention and that the invention is not limited to the embodiments illustrated for explanatory purpose.

In one embodiment, a method of forming a semiconductor device may include, but is not limited to, the following processes. A first insulating film is formed on an etching stopper film. The etching stopper film has resistance to a wet-etching. A second insulating film is formed on the first insulating film. The second insulating film is higher in removing rate of the wet-etching than the first insulating film. An opening is formed, which penetrates the etching stopper and the first and second insulating films. A bottom electrode is formed in the opening. The second insulating film is removed by carrying out the wet-etching to expose an outside wall of the bottom electrode, wherein at least a part of the first insulating film remains on the etching stopper film after the wet-etching.

In some cases, the second insulating film is removed while the first insulating film covers the etching stopper film and a lower portion of the bottom electrode.

In some cases, the first insulating film prevents that an etchant penetrates through a boundary between the etching stopper and the bottom electrode, while carrying out the wet etching process.

In some cases, the method may further include forming a contact plug in an interlayer insulating film, and forming the etching stopper film on the interlayer insulating film and the contact plug. The opening is formed over the contact plug. The bottom electrode connects electrically to the contact plug.

In some cases, the method may include, but is not limited to, forming a third insulating film on the second insulating film. The third insulating film is higher in removing rate of the wet-etching than the second insulating film. The opening is formed by selectively side-etching the second insulating film. The wet-etching is carried out to remove the second and third insulating films.

In some cases, the second insulating film may be, but is not limited to, a silicon oxide film including impurity. The third insulating film may be, but is not limited to, a silicon oxide film which is substantially free of impurity.

In some cases, the method may include, but is not limited to, forming a fourth insulating film over the second insulating film. The fourth insulating film has wet-etching resistance. The method may include, but is not limited to, patterning the fourth insulating film to form a supporter that supports the bottom electrode, after forming the bottom electrode and before removing the second insulating film.

In some cases, the fourth insulating film may be, but is not limited to, a silicon nitride film.

In some cases, the method may include, but is not limited to, forming a conductive pad connected to the contact plug. The conductive pad is larger in horizontal size than the contact plug. The bottom electrode connects directly to the conductive pad.

In some cases, the first insulating film may be, but is not limited to, a silicon oxide film which is substantially free of impurity. The second insulating film may be, but is not limited to, a silicon oxide film which contains at least phosphorus as impurity.

In some cases, the first insulating film may be, but is not limited to, a first boro-phospho-silicate glass film having a first phosphorous concentration. The second insulating film may be, but is not limited to, a second boro-phospho-silicate glass film having a second phosphorous concentration which is higher than the first phosphorous concentration.

In some cases, the etching stopper film comprises a silicon nitride film and the wet-etching is carried out by using an etchant containing hydrofluoric acid.

In some cases, the bottom electrode comprises a cylindrically shaped electrode.

In some cases, the bottom electrode comprises a column shaped electrode.

In another embodiment, a method of forming a device may include, but is not limited to, the following processes. An opening is formed in a first insulating layer. A conductive layer is formed on a bottom and a side surface of the opening. The conductive layer extends upwardly. The first insulating layer is selectively removed by a wet-etching to expose an outside wall of the conductive layer except for a lower portion thereof, while a remaining portion of the first insulating layer covers the lower portion of the conductive layer.

In some cases, the remaining portion of the first insulating layer prevents that an etchant of the wet-etching penetrates through a boundary between the conductive layer and the remaining portion of the first insulating layer, while carrying out the wet etching process.

In some cases, the conductive layer may be, but is not limited to, a bottom electrode of a capacitor.

In some cases, the method may further include, but is not limited to, the following processes. A contact plug is formed in an interlayer insulating film. An etching stopper film is formed on the interlayer insulating film and the contact plug. The etching stopper film has resistance to the wet-etching. A first insulating film is formed on the etching stopper film. A second insulating film is formed on the second insulating film. The second insulating film is higher in removing rate of the wet-etching than the first insulating film. The conductive layer may include, but is not limited to, a stack of the etching stopper film, the first insulating film and the second insulating film.

In some cases, the method may further include, but is not limited to, forming a third insulating film over the second insulating film. The third insulating film is higher in removing rate of the wet-etching than the second insulating film. The opening may be formed by selectively side-etching the second insulating film. The wet-etching may be carried out to remove the second and third insulating films.

In still another embodiment, a method of forming a semiconductor device may include, but is not limited to, the following processes. A contact plug may be formed in an interlayer insulating film. An etching stopper film may be formed on the interlayer insulating film and the contact plug. A first insulating film may be formed on the etching stopper film. The etching stopper film has resistance to a wet-etching. A second insulating film may be formed on the second etching stopper. The second insulating film is higher in removing rate of the wet-etching than the first insulating film. An opening is formed, which penetrates the etching stopper and the first and second insulating films. A bottom electrode is formed in the opening. The second insulating film is removed by carrying out the wet-etching to expose an outside wall the bottom electrode. The second insulating film is removed while the first insulating film covers the etching stopper film and a lower portion of the bottom electrode. The second insulating film prevents that an etchant penetrates through a boundary between the etching stopper and the bottom electrode, while carrying out the wet-etching.

### Semiconductor Device:

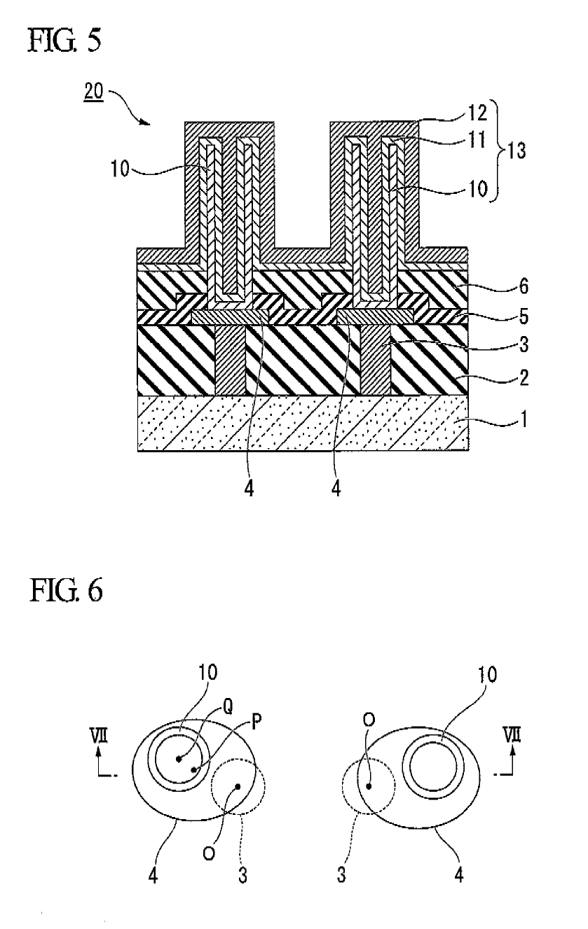

A semiconductor device will be described. The semiconductor device can be obtained by processes that will be described later. The semiconductor device of the invention is configured so that an etching stopper film is provided on an interlayer insulating film, and a first insulating film is provided on the etching stopper film. An example of the semiconductor device will be described with reference to FIG. 5. FIG. 5 is a cross-sectional elevation view illustrating a DRAM device 20.

As shown in FIG. 5, the DRAM device 20 may include, but is not limited to, a semiconductor substrate 1, an interlayer insulating film 2, an etching stopper film 5, a first insulating film 6, and a bottom electrode 10. The interlayer insulating film 2 is provided on the semiconductor substrate 1. A contact plug 3 is buried in the interlayer insulating film 2. The etching stopper film 5 is provided on the interlayer insulating film 2. The first insulating film 6 is provided on the etching stopper film 5. The bottom electrode 10 is provided, which penetrates the first insulating film 6 and the etching stopper film 5. The bottom electrode 10 is connected to the contact plug 3 through a contact pad 4. The bottom electrode 10 is provided so that a center axis thereof is substantially aligned to a center axis of the contact pad 4 and the contact plug 3. A dielectric film 11 is provided on the bottom electrode 10 so as to cover the surface thereof. A top electrode 12 is provided on the dielectric film 11 so as to cover the surface of the dielectric film 11, thereby forming a capacitor 13. The capacitor 13 includes the bottom electrode 10, the dielectric film 11 and the top electrode 12. Semiconductor devices such as MOS transistors, which are not shown, have been formed in the semiconductor substrate. These semiconductor devices are buried in the interlayer insulating film 2.

### Method of Forming the Semiconductor Device:

A method of forming a semiconductor device of the embodiment may include, but is not limited to, the following processes. Film formation processes are carried out as follows. An etching stopper film is formed on an interlayer insulating film in which a contact plug is buried. The etching stopper film performs as an etching stopper against a wet etching. A first insulating film is formed on the etching stopper film. A second insulating film is formed on the first insulating film. The second insulating film is higher in wet etching rate than that of the first insulating film. An opening formation process is carried out as follows. An opening is formed which penetrates the etching stopper film, the first insulating film and the second insulating film. A bottom electrode formation process is carried out. A bottom electrode of a capacitor is provided in the opening. A removal process is carried out as follows. The second insulating film is removed by a wet etching so that the bottom electrode is exposed.

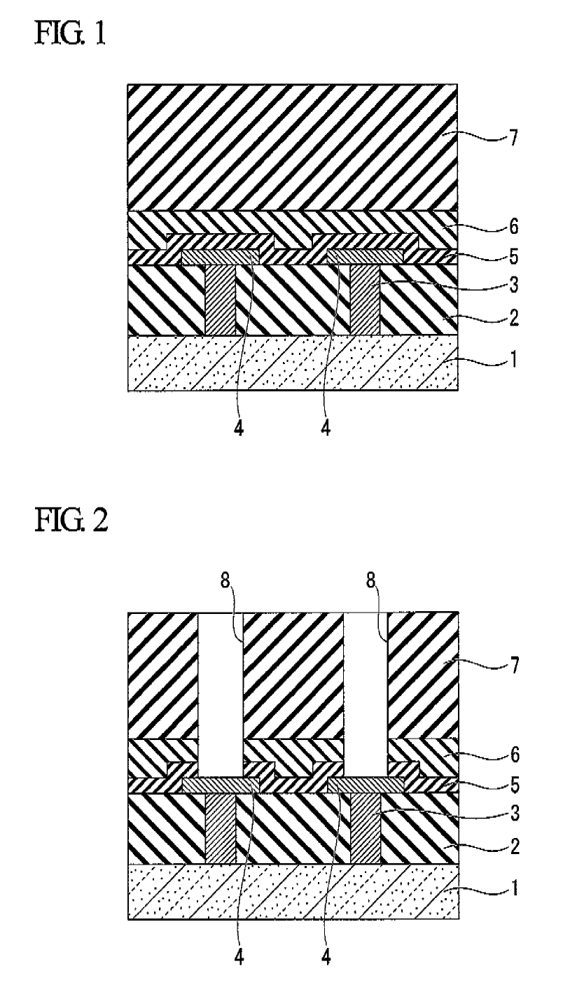

An embodiment of the method of forming the semiconductor device will be described with reference to FIGS. 1 to 5. FIGS. 1 to 4 are fragmentary cross sectional elevation views illustrating semiconductor devices in sequential steps involved in a method of forming the semiconductor device including capacitors of FIG. 5.

### Film Formation Process:

Film formation processes are carried out as follows. An etching stopper film is formed on an interlayer insulating film in which a contact plug is buried. The etching stopper film performs as an etching stopper against a wet etching. A first insulating film is formed on the etching stopper film. A second insulating film is formed on the first insulating film. The second insulating film is higher in wet etching rate than that of the first insulating film. The film forming process will be described with reference to FIG. 1.

As shown in FIG. 1, the interlayer insulating film 2 is provided by depositing a silicon oxide film on the semiconductor substrate 1. Transistor elements have been formed in the semiconductor substrate 1. The contact plug 3 is provided in the interlayer insulating film 2, using polycrystalline silicon (Poly-Si) or tungsten (W). The contact plug 3 is connected to the semiconductor substrate 1. The interlayer insulating film 2 having the contact plug 3 extends over the semiconductor substrate 1. The contact pad 4 is provided on the interlayer insulating film 2 so that the contact pad 4 is connected to the top surface of the contact plug 3. The contact pad 4 is a conducting pad. The contact pad 4 has a film thickness of about 30 nm. The contact pad 4 may be a stack of a tungsten nitride (WN) film and a tungsten (W) film. The etching stopper film 5 of silicon nitride has a film thickness of about 50 nm. The etching stopper film 5 covers the surfaces of the contact pad 4 and the interlayer insulating film 2. The etching stopper film 5 performs as an etching stopper when an opening is formed by a wet etching process.

The first insulating film 6 is provided on the etching stopper film 5. The first insulating film 6 has a film thickness of about 500 nm. The second insulating film 7 is further provided on the first insulating film 6. The second insulating film 7 has a film thickness of about 1500 nm.

The second insulating film 7 contains silicon oxide as a main ingredient. The etching rate of the second insulating film 7 is higher than the etching rate of the first insulating film 6.

The second insulating film 7 may include a BPSG (Boro-Phospho-Silicate Glass) film. The BPSG film is a silicon oxide film containing boron and phosphorus as impurity dopant. The BPSG film uses a TEOS (tetraethoxysilane; Tetra Ethylene Ortho Silicate) as a raw material. The BPSG film can be provided by a plasma CVD method (Chemical Vapor Deposition method) using TEB (tri-ethyl borate) and TROP (tri-methyl ortho phosphate) as raw materials of the dopant.

The etching rate can be adjustable by adjusting the impurity concentration of the second insulating film 7. It is preferable that a ratio of an etching rate of second insulating film to an etching rate of the first insulating film is adjusted so that the etching rate ratio is about 10/1.

The first insulating film 6 is configured so that silicon oxide is used as a main ingredient. The etching rate of the first insulating film 6 is lower than that of the second insulating film 7.

The first insulating film 6 is provided by a plasma CVD method using, for example, TEOS as raw materials. The first insulating film 6 includes a silicon oxide film in which impurities are not effectively contained. Alternatively, the first insulating film may include a silicon oxide film doped with impurities in a range that the etching rate thereof is lower than that of the second insulating film 7 in a removal process described later. When the doped silicon oxide film, for example, the second insulating film 7 is used as a BPSG film, it is possible to reduce the etching rate thereof by using the BPSG film having lower doping concentration of phosphorus than that of the second insulating film 7. When the doped silicon oxide film is used in the first insulating film 6, the doping concentration of the impurities may be adjusted so that the ratio of the etching rate is as large as possible. From the viewpoint of increasing the ratio of the etching rate of the first insulating film 6 and the second insulating film 7 in this manner, it is preferable that the first insulating film 6 is a silicon oxide film containing substantially no impurities.

### Opening Formation Process:

An opening formation process is a process to form an opening which penetrates the etching stopper film, the first insulating film and the second insulating film which are provided in the film forming process. The opening forming process will be described with reference to FIG. 2.

By an anisotropic dry etching process, an opening (hole) 8 is formed which penetrates the etching stopper film 5, the first insulating film 6 and the second insulating film 7, so that the surface of the contact pad 4 is exposed. At this time, both of the first insulating film 6 and the second insulating film 7 are insulating films which use silicon oxide as main material. No changes to the dry etching conditions are necessary. The opening 8 can easily be formed, which penetrates the first insulating film 6 and the second insulating film 7. Since the etching stopper film 5 has a film thickness of about 50 nm, which is very thin, the opening 8 penetrating the etching stopper film 5 can be easily formed.

It is possible to use a dry etching method using etching gases for forming the opening 8. The etching gases may be for example, C₄F₈, C₅F₈, C₄F₆, and CHF₃, which contains, for example, fluorine, in the anisotropic dry etching.

### Bottom Electrode Formation Process:

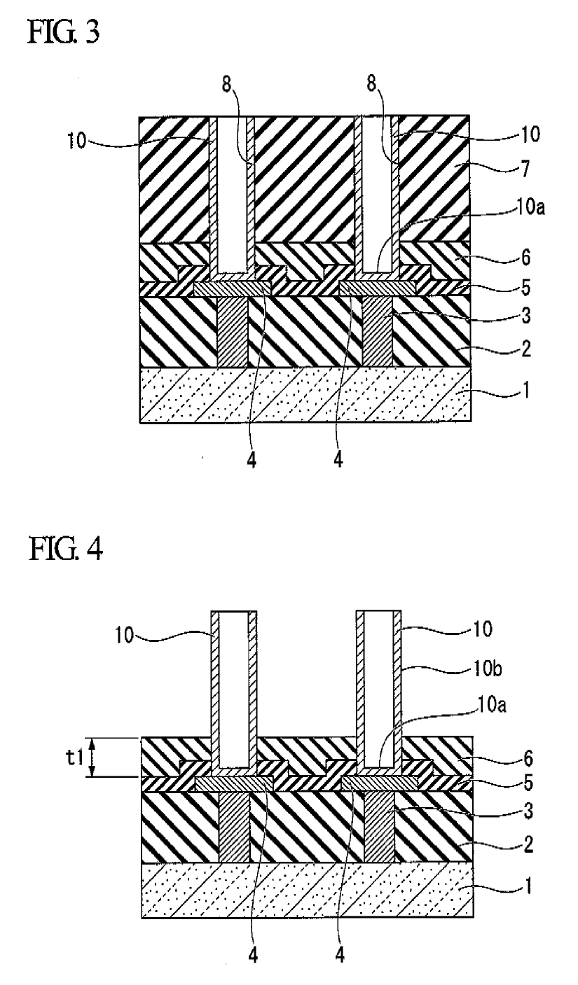

A bottom electrode formation process is a process of providing the bottom electrode of the capacitor in the opening formed by the opening forming process. The bottom electrode formation process will be described with reference to FIG. 3.

As shown in FIG. 3, a bottom electrode film having a film thickness of about 30 nm is provided on the internal surface of the opening 8. After the bottom electrode materials axe formed on the top surface of the opening 8 and the second insulating film 7, the cylindrical bottom electrode 10 is provided by selectively removing the bottom electrode film so that the bottom electrode film remains only on the inner wall of the opening 8. The selective removal can be performed by a dry etching or a CMP (Chemical Mechanical Polishing).

The opening 8 is filled up with a burying film such as a photoresist film or a silicon oxide film. A dry etching or a CMP may be performed in order to protect the bottom 10a of the bottom electrode 10. The burying film is provided in order to prevent the etching gases used in a dry etching or slurry used in CMP from flowing into the opening 8.

When the opening is filled up with the silicon oxide film as a burying film, the burying film is removed by a removal process described later. The silicon oxide film may reside within the opening 8. In this case, the burying film may preferably be a film having the same material as that of the second insulating film 7. When the opening is filled up with the photoresist film as a burying film, the bottom electrode 10 is formed, and then the burying film is removed from the inside of the opening 8 by aching using oxygen gas.

The bottom electrode 10 may include, for example, at least one of titanium nitride (TiN), titanium (Ti), tungsten (W), platinum (Pt), and ruthenium (Ru), which are high melting point metals, or a stack of films of those materials. The bottom electrode 10 may preferably include titanium nitride.

### Removal Process:

A removal process is a process of removing the second insulating film by wet etching and exposing the bottom electrode. The removal process will be described with reference to FIGS. 3 and 4.

The second insulating film 7 is removed by wet etching which uses etchant containing hydrofluoric acid (HF). The removal process or the wet etching process is terminated so that the first insulating film 6 has a film thickness t1 of about 300 nm. In this case, the first insulating film 6 has a lower etching rate than that of the second insulating film 7. The second insulating film 7 is removed. The first insulating film 6 is not easily removed. It is possible to that the first insulating film 6 has a film thickness which is suitable to remove the second insulating film 7 and expose the sidewall (outer wall) 10b of the bottom electrode 10.

The silicon oxide film 6 having a sufficient film thickness prevents penetration of the etchant through the path B shown in FIG. 13.

The contact pad 4 contacting the bottom 10a of the bottom electrode 10 is provided. It is possible to prevent penetration of the etchant through the path A shown in FIG. 13.

The inside of the opening 8 is filled up with the silicon oxide film by the bottom electrode formation process. The silicon oxide film is simultaneously removed by wet etching for removing the second insulating film 7. The bottom 10a of the bottom electrode 10 is exposed to the etchant for a short period of time, to thereby prevent penetration of the etchant into the interlayer insulating film 2 through the path A of FIG. 13. When the inside of the opening 8 is filled up with the silicon oxide film, it is possible to prevent penetration of the etchant through the path A even the contact pad 4 is not provided.

### Capacitor Formation Process:

The bottom electrode 10 exposed by the removal process can be used as a capacitor through the following capacitor formation process.

As shown in FIG. 5, the dielectric film 11 is provided so that the dielectric film 11 covers the surface of the exposed bottom electrode 10. The dielectric film 11 is provided on each of surfaces of the internal surface and the external surface of the bottomed cylindrical bottom electrode 10. The dielectric film 11 is provided on not only the surface of the bottom electrode 10, but also the surface of the first insulating film 6. The top electrode 12 is provided so that the top electrode 12 covers the surface of the dielectric film 11. The capacitor 13 is formed which includes the bottom electrode 10, the dielectric film 11 and the top electrode 12.

The dielectric film 11 can be formed by, for example, an ALD method (Atomic Layer Deposition method). The dielectric film 11 may include, for example, at least one of aluminum oxide (Al₂O₃), zirconium oxide (ZrO₂), and hafnium oxide (HfO₂). A film thickness of the dielectric film 11 may be in the range of, for example, 6 nm to 10 nm.

The top electrode 12 can be formed by, for example, a CVD method. The top electrode 12 may include at least one of titanium nitride, titanium, tungsten, platinum, ruthenium and the like, or a stack of films of those materials. A film thickness of the top electrode 12 may be, for example, about 100 nm.

It is possible to obtain the DRAM device 20 through the above-mentioned processes.

As described above, in the method of forming the semiconductor device of the invention, the second insulating film is removed by the removal process using the wet etching. Since the first insulating film has a lower etching rate than that of the second insulating film, the first insulating film with a film thickness will reside. Also it is possible to prevent that the etching stopper film having a relatively thin film thickness is excessively etched. It is possible to prevent that the etchant is penetrated through the boundary between the bottom electrode and the etching stopper film or the first insulating film into the interlayer insulating film of the lower layer. The contact pad can prevent that the etchant is penetrated from the bottom of the bottom electrode to the interlayer insulating film of the lower layer. Generation of defective products due to penetration of the etchant into the interlayer insulating film is prevented. Improvement in the manufacturing yield of the semiconductor device is achieved. Both the first insulating film 6 and the second insulating film 7 contain silicon oxide as a main ingredient. The opening can be formed in the opening formation process without changing the wet etching. Penetration of the etchant into the lower layer can be prevented by the first insulating film. It is not necessary to increase the film thickness of the etching stopper film. The etching stopper film located at the bottom of the opening can easily be etched in the opening forming process. It is possible to easily form the opening having a high aspect ratio. For this reason, it is possible to increase capacitance of the capacitor by increasing the height of the bottom electrode.

The invention is not limited to the above-mentioned embodiments.

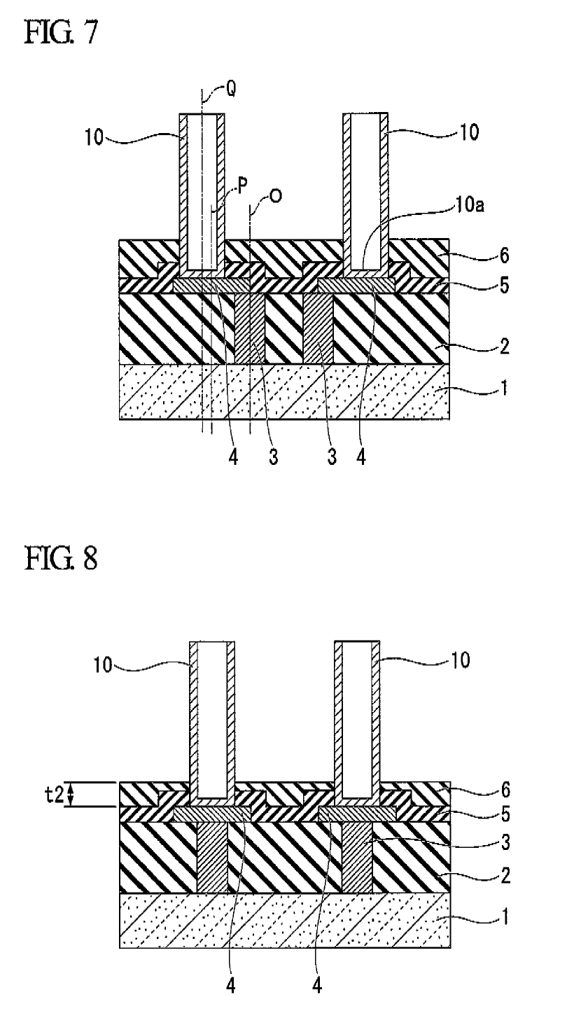

In the above-mentioned embodiments, the contact plug 3, the contact pad 4 and the bottom electrode 10 are disposed so that the center axis of the bottom electrode 10 is substantially aligned to the center axes of the contact pad 4 and the contact plug 3. The alignments of the center axes of the contact plug 3, the contact pad 4, and the bottom electrode 10 are not essential. Misalignments of the contact plug 3, the contact pad 4, and the bottom electrode 10 will be described with reference to FIGS. 6 to 7. FIG. 6 is a plan view illustrating positional relationships among the contact plug 3, the contact pad 4, and the bottom electrode 10. FIG. 7 is a cross-sectional view taken along the line VII-VII of FIG. 6, illustrating the semiconductor device after the removal process.

As shown in FIGS. 6 and 7, there are misalignments among a central axis O of the contact plug 3, a central axis P of the contact pad 4, and a central axis Q of the bottom electrode 10. The top surface of the contact plug 3 may be covered, but not entirely or not perfectly by the contact pad 4 as shown in FIG. 6. In this case, the contact pad 4 ensures electrical connection between the bottom electrode 10 and the contact plug 3.

In the film formation process, the contact pad 4 can be formed so that the contact pad 4 contacts partially the top surface of the contact plug 3.

In the opening forming process, the opening can be provided while the center axis of the opening is misaligned to the center axis of the contact pad 4 or the central axis of the contact plug. The bottom electrode 10 is provided so that the entire surface of the bottom 10a contacts the contact pad 4. It is possible to optimize the planar shape of the bottom electrode 10 and the position of the bottom 10a of the bottom electrode 10. It is possible to form the bottom electrodes at a constant interval. The electrode size or the planar shape can be increased while preventing the short circuit formation between adjacent bottom electrodes. It is possible to increase the capacitance of the capacitors.

Even when the contact plug 3, the contact pad 4, and the bottom electrode 10 are disposed in the above-manner, it is possible to prevent penetration of the etchant through the etching stopper film 5 into the interlayer insulating film 2 of the lower layer.

In the above-mentioned embodiment, the wet etching process is performed in the removal process so that the first insulating film 6 has the film thickness t1 of about 300 nm. The removal process is not limited thereto. As shown in FIG. 8, after the second insulating film is removed, the film thickness t2 of the first insulating film 6 may be in the range of 50 nm to 100 nm by further continuing the wet etching. The first insulating film 6 has a slower etching rate in the wet etching. It is easy to control the thicknesses of the remaining films. Even when the etching stopper film 5 is exposed to the etchant due to variation of the film thicknesses of the first insulating film 6 and the second insulating film, it is possible to avid penetration of the etchant due to a shortened period of time when exposed to the etchant.

As shown in FIG. 8, the film thickness t2 of the first insulating film 6 is equal to or less than 100 nm. It is preferable to form the structure where the contact pad 4 is provided. The path to the interlayer insulating film 2 becomes longer by disposing the contact pad 4. Even when the etching stopper film 5 of the bottom of the bottom electrode 10 is exposed, penetration of the etchant in the path B (FIG. 13) can be prevented.

As described above, capacitance of the capacitor can be increased by reduce the film thickness t2 of the first insulating film 6 as many as possible.

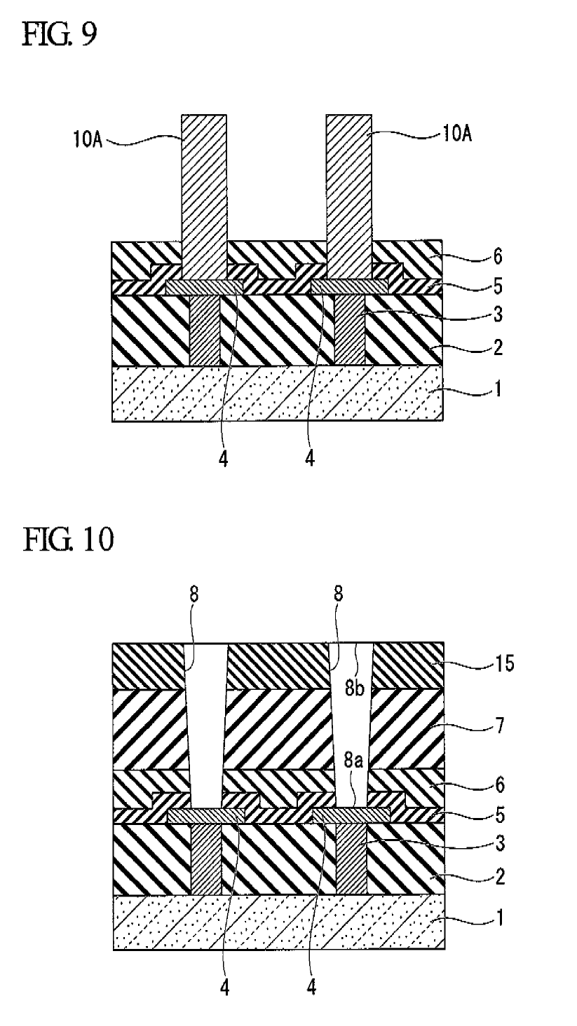

In the above-mentioned embodiment, the bottom electrode 10 is formed in the bottom-closed cylindrical shape. The shape of the bottom electrode 10 is not limited thereof. As shown in FIG. 9, the bottom electrode may be formed as a pillar-shaped or column-shaped bottom electrode 10A which is not a hollow structure.

The pillar-shaped bottom electrode 10A can be formed by filling the inside space of the opening 8 up with the bottom electrode material.

Penetration of the etchant through the path A (see FIG. 13) is effectively prevented by providing the above-mentioned pillar-shaped bottom electrode 10A.

In the above-mentioned embodiment, the first insulating film 6 and the second insulating film 7 are provided on the etching stopper film 5 by the film forming process. It is possible to modify this structure. As shown in FIG. 10, a silicon oxide film 15 substantially free of impurities may be provided on the second insulating film 7 as a third insulating film. The third insulating film having a lower wet etching rate than that of the second insulating film is provided. The above-mentioned silicon oxide film 15 can be provided by, for example, a plasma CVD method.

The aspect ratio of the opening 8 is increased by shrinkage of the semiconductor device. The opening 8 has the bottom 8a which is smaller in area than the top surface 8b. The opening 8 can easily be formed in a tapered shape by a dry etching when the opening 8 is formed as shown in FIG. 10. When the bottom electrode is provided using the taper-shaped opening 8, the bottom electrode having a smaller surface area than a desired surface area can easily be formed. When the surface area of the bottom electrode is insufficient, the desired capacitance is not obtained.

The silicon oxide film 15 is provided by the film formation process. The opening 8 is formed by the opening formation process. The second insulating film 7 of the opening 8 is selectively side-etched by wet etching which uses the etchant such as an ammonia hydrogen peroxide mixture (APM). The side etching process expands the hole in the second insulating film 7.

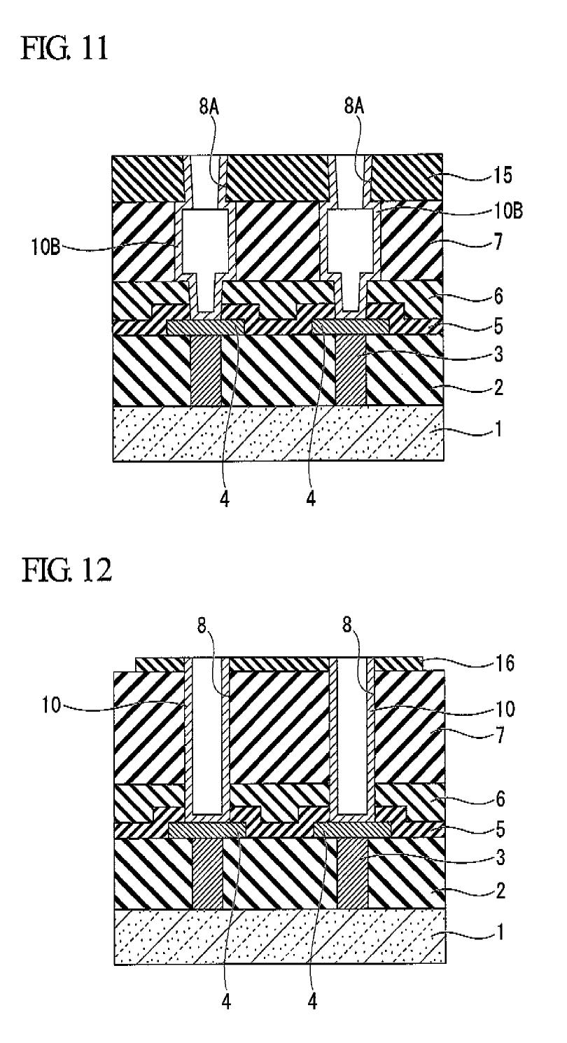

As shown in FIG. 11, a bottom electrode 10B is provided by depositing the bottom electrode materials in the internal surface of an opening 8A in which the hole of the second insulating film 7 is expanded by the above-mentioned expansion operation. Further, in the removal process, the second insulating film 7 is removed, and the silicon oxide film 15 is removed, to thereby expose the bottom electrode 10B.

Since the bottom electrode 10B has a large surface area compared to the bottom electrode 10 shown in FIG. 4, capacitance of the capacitor can be increased.

In this manner, it is possible to easily form such a bottom electrode having a large surface area as the bottom electrode 10B by forming the third insulating film in the film forming process, and providing the expansion operation to the opening forming process.

As shown in FIG. 12, a silicon nitride film 16 may be formed on the upper portion of the second insulating film 7 as the third insulating film. After the bottom electrode 10 is formed, the silicon nitride film 16 is patterned, and the patterned silicon nitride film 16 is formed as a belt-like pattern extending up to the outside of a memory cell region in a predetermined direction.

The patterned silicon nitride film 16 functions as a support for holding the upper end of the bottom electrode 10. For this reason, it is possible to prevent the bottom electrode 10 from being destroyed at the time of the removal process. Even when the height of the bottom electrode 10 is made higher in order to increase capacitance of the capacitor, it is possible to prevent the bottom electrode 10 from being collapsed.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A method of forming a semiconductor device, the method comprising:
forming a first insulating film on an etching stopper film, the etching stopper film having resistance to a wet-etching;
forming a second insulating film on the first insulating film, the second insulating film being higher in removing rate of the wet-etching than the first insulating film;
forming an opening which penetrates the etching stopper and the first and second insulating films;
forming a bottom electrode in the opening; and
removing the second insulating film by carrying out the wet-etching to expose an outside wall of the bottom electrode, at least a part of the first insulating film remaining on the etching stopper film after the wet-etching.

2. The method according to claim 1, wherein the first insulating film prevents that an etchant penetrates through a boundary between the etching stopper and the bottom electrode, while carrying out the wet etching process.

3. The method according to claim 1, further comprising:
forming a contact plug in an interlayer insulating film; and
forming the etching stopper film on the interlayer insulating film and the contact plug,
wherein forming the opening comprises forming the opening over the contact plug, and
the bottom electrode connects electrically to the contact plug.

4. The method according to claim 1, further comprising:
forming a third insulating film on the second insulating film, the third insulating film being higher in removing rate of the wet-etching than the second insulating film,
wherein forming the opening further comprises selectively side-etching the second insulating film, and
the wet-etching is carried out to remove the second and third insulating films.

5. The method according to claim 4, wherein the second insulating film comprises a silicon oxide film including impurity, and the third insulating film comprises a silicon oxide film which is substantially free of impurity.

6. The method according to claim 1, further comprising:
forming a fourth insulating film over the second insulating film, the fourth insulating film having wet-etching resistance; and
patterning the fourth insulating film to form a supporter that supports the bottom electrode, after forming the bottom electrode and before removing the second insulating film.

7. The method according to claim 6, wherein the fourth insulating film comprises a silicon nitride film.

8. The method according to claim 3, further comprising:
forming a conductive pad connected to the contact plug, the conductive pad being larger in horizontal size than the contact plug,
wherein the bottom electrode connects directly to the conductive pad.

9. The method according to claim 1, wherein the first insulating film comprises a silicon oxide film which is substantially free of impurity, and the second insulating film comprises a silicon oxide film which contains at least phosphorus as impurity.

10. The method according to claim 1, wherein the first insulating film comprises a first boro-phospho-silicate glass film having a first phosphorous concentration and the second insulating film comprises a second boro-phospho-silicate glass film having a second phosphorous concentration which is higher than the first phosphorous concentration.

11. The method according to claim 1, wherein the etching stopper film comprises a silicon nitride film and the wet-etching is carried out by using an etchant containing hydrofluoric acid.

12. The method according to claim 1, wherein the bottom electrode comprises a cylindrically shaped electrode.

13. The method according to claim 1, wherein the bottom electrode comprises a column shaped electrode.

14. A method of forming a device, the method comprising:
forming an opening in a first insulating layer;
forming a conductive layer on a bottom and a side surface of the opening, the conductive layer extending upwardly; and
selectively removing the first insulating layer by a wet-etching to expose an outside wall of the conductive layer except for a lower portion thereof, while a remaining portion of the first insulating layer covering the lower portion of the conductive layer.

15. The method as claimed in claim 14, wherein the remaining portion of the first insulating layer prevents that an etchant of the wet-etching penetrates through a boundary between the conductive layer and the remaining portion of the first insulating layer, while carrying out the wet etching process.

16. The method as claimed in claim 14, wherein the conductive layer comprises a bottom electrode of a capacitor.

17. The method according to claim 14, further comprising:
forming a contact plug in an interlayer insulating film;
forming an etching stopper film on the interlayer insulating film and the contact plug, the etching stopper film having resistance to the wet-etching;
forming a first insulating film on the etching stopper film; and
forming a second insulating film on the second insulating film, the second insulating film being higher in removing rate of the wet-etching than the first insulating film,
wherein the conductive layer comprises a stack of the etching stopper film, the first insulating film and the second insulating film.

18. The method according to claim 17, further comprising:
forming a third insulating film over the second insulating film, the third insulating film being higher in removing rate of the wet-etching than the second insulating film,
wherein forming the opening further comprises selectively side-etching the second insulating film, and
the wet-etching is carried out to remove the second and third insulating films.

19. A method of forming a semiconductor device, the method comprising:
forming a contact plug in an interlayer insulating film;
forming an etching stopper film on the interlayer insulating film and the contact plug,
forming a first insulating film on the etching stopper film, the etching stopper film having resistance to a wet-etching;
forming a second insulating film on the second etching stopper, the second insulating film being higher in removing rate of the wet-etching than the first insulating film;
forming an opening which penetrates the etching stopper and the first and second insulating films;
forming a bottom electrode in the opening; and
removing the second insulating film by carrying out the wet-etching to expose an outside wall of the bottom electrode,
wherein the second insulating film is removed while the first insulating film covers the etching stopper film and a lower portion of the bottom electrode, the second insulating film prevents that an etchant penetrates through a boundary between the etching stopper and the bottom electrode, while carrying out the wet-etching.
